(19) United States
(12) Patent Application Publication
(10) Pub. No.: US 2015/0096685 A1
(43) Pub. Date: Apr. 9, 2015

(54) VACUUM PROCESSING APPARATUS

(71) Applicant: Hitachi High-Technologies Corporation, Tokyo (JP)

(72) Inventors: Kohei Sato, Tokyo (JP); Akitaka Makino, Tokyo (JP); Hiromichi Kawasaki, Tokyo (JP)

(21) Appl. No.: 14/183,554

(22) Filed: Feb. 19, 2014

(30) Foreign Application Priority Data
Oct. 8, 2013 (JP) 2013-210655

(51) Int. Cl. H01J 37/32

(52) U.S. Cl. CPC H01J 37/32733; H01J 37/32899
USPC 156/345.32; 156/345.31

(57) ABSTRACT

A plasma processing apparatus includes processing units, each of which subjects a sample to processing inside a processing chamber in a vacuum vessel, vacuum transfer chambers which are coupled to the processing units and each have an interior where a sample is transferred under reduced pressure, an intermediate chamber which has, in an interior, a space where a transferred sample is housed, a buffer chamber which is capable of housing a sample arranged in an interior of the vessel, a mounting table which is arranged in the buffer chamber and is adjusted to a prescribed temperature and on which a sample is placed, an opening through which a sample is taken in or out, and a lid member which opens or hermetically closes the opening, and a sample is transferred between the processing unit and a lock chamber via the buffer chamber.

### BACKGROUND OF THE INVENTION

The present invention relates to a vacuum processing apparatus for reducing the pressure in a processing chamber in a vacuum vessel coupled to a vacuum transfer vessel and processing a substrate-like sample, such as a semiconductor wafer, in the processing chamber and, in particular, to a vacuum processing apparatus having an intermediate chamber which is coupled to and between a plurality of vacuum transfer vessels and via which a sample is transferred.

As a prior-art example of such a vacuum processing apparatus, there is known the vacuum processing apparatus disclosed in JP-A-2012-138542.

The vacuum processing apparatus is a vacuum processing apparatus which places a sample, such as a semiconductor wafer, on a sample stage and processes the sample in an interior under reduced pressure. For example, the vacuum processing apparatus removes a target film on a surface of the sample or deposits a film on the surface of the sample. In this processing, for example, chemically active plasma is formed by introducing process gas into a vacuum processing chamber and causes a chemical reaction between ions or active gaseous species and the sample. The processing proceeds through the chemical reaction.

Whether the chemical reaction occurs, whether byproducts of the chemical reaction are detached and emitted in a gaseous state from the surface of the sample, or whether the byproducts are deposited in a solid state on the surface of the sample is significantly affected by the temperature of the sample. In order to, for example, detach and emit a material with low vapor pressure in a gaseous state of the byproducts from the surface of the sample, the pressure of the processing chamber needs to be lowered or the sample temperature needs to be raised. From a practical standpoint, there is a limit to the pressure of the processing chamber, under which processing is possible, the sample temperature needs to be raised to a sufficiently high temperature.

As described above, the temperature of a sample needs to be controlled according to an intended process. A process is thus adopted of controlling the sample temperature to a desired temperature by controlling the temperature of the sample stage.

As a way to control the sample stage temperature, temperature-controlled heat exchange liquid is made to flow through the sample stage or the sample stage has a built-in heater and is subjected to heating control.

The temperature of the sample is controlled by heat transfer from the sample stage. For efficient heat transfer between a sample and the sample stage, a process, such as sucking the sample and the sample stage to stick to each other by, e.g., electrostatic suction force and forming a very shallow groove in a sample mounting surface of the sample stage to fill a clearance space between the sample and the sample stage with heat transfer gas, such as helium, is performed. Alternatively, the sample may be put on the sample stage controlled to a high temperature without electrostatic suction and be heated.

If processing is performed with a sample temperature as high as, for example, about 200° C. to 300° C. in the process of electrostatically sucking a sample to stick to the sample stage, the sample stage is constantly controlled to and maintained at a high temperature, the sample is sucked by electrostatic suction force to stick to the sample stage controlled to a high temperature after being placed on the sample stage and is heated with the heat conduction gas permeating the clearance space as a heat transfer medium. After the wafer temperature reaches a temperature meeting a processing condition, the processing is started.

If a sample before processing is mounted on the high-temperature sample stage and is heated in a sucked state on the sample stage in the conventional technique, since the sample expands thermally in a state sucked to stick to the sample stage, a back surface of the sample and an upper surface of the sample stage are abraded to produce minute contaminating matters or change the surface roughness of the upper surface of the sample stage. This changes the efficiency of heat transfer brought about by contact between the sample and the sample stage to lower the controllability of the sample temperature. Due consideration has not given to such a problem in the conventional technique.

If a sample is not sucked to stick to the sample stage, the heat conduction gas cannot be introduced into the clearance between the sample and the sample stage, the pressure between the sample and the sample stage is a low pressure almost equal to the pressure of the processing chamber, and the heat transfer efficiency is low. It is thus practically difficult to sufficiently heat the sample before the processing starts. As an alternative way to sufficiently heat the sample, heating the sample by a different heat source in the processing chamber, such as heat input from plasma during plasma processing, is available. However, in this configuration, the temperature of the sample rises gradually during processing, and strict control of the sample temperature during the processing is difficult. Due consideration has not given to the difficulty in the conventional technique.

Additionally, a sample at a high temperature after the plasma processing needs to be cooled to the heatresistant temperature of a cassette in an atmospheric-pressure atmosphere or a lower temperature when the sample is returned to the cassette. A robot which transfers a sample in an air atmosphere generally sucks a sample with vacuum to stick to an upper surface of a hand to hold the sample on the hand. The temperature of the sample may fall locally at a contact surface between the hand and the sample to produce a temperature gradient between a high-temperature portion and a low-temperature portion in the sample. This may cause thermal stress to result in damage to the sample.

There is thus a need to cool a sample before the sample is transferred to the robot in the air atmosphere after completion of vacuum processing. In response to such a need, a stage or the like which cools a sample has been arranged in a transfer path on the vacuum side, and a sample has been arranged on the stage and been cooled. The installment of the stage or the like increases a floor area of an entire apparatus to increase costs for maintaining the apparatus or a long duration of sample cooling reduces throughput. Insufficient consideration has been given to the problem.

### SUMMARY OF THE INVENTION

An object of the present invention is to provide a plasma processing apparatus for controlling the temperature of a sample within a wide range of high or low temperatures to perform plasma processing which inhibits production of contaminating matters and abrasion of a surface of a sample stage and has high productivity.

Another object is to provide a plasma processing apparatus capable of efficiently cooling a sample at a high temperature after processing, before transferring the sample to a transfer robot in an air atmosphere.

The above-described objects are accomplished by a vacuum processing apparatus comprising a plurality of processing units, each of which has a processing chamber arranged in an interior of a vacuum vessel and reduced in pressure and subjects a sample to processing inside the processing chamber, a plurality of vacuum transfer chambers which are coupled to the processing units and each have an interior where the sample is transferred under reduced pressure, and an intermediate chamber which is arranged between and coupled to two of the vacuum transfer chambers and has, in an interior, a space where the transferred sample is housed, wherein the apparatus further comprises a buffer chamber which is coupled to the intermediate chamber and is capable of housing the sample arranged in the interior of the vessel, a mounting stage which is arranged in the buffer chamber and is adjusted to a prescribed temperature and on which the sample is placed, an opening which is arranged between the buffer chamber and the interior of the intermediate chamber and through which the sample is taken in or out, and a lid member which opens or hermetically closes the opening, and the sample is transferred between the processing unit and a lock chamber via the buffer chamber.

Other objects, features and advantages of the invention will become apparent from the following description of the embodiments of the invention taken in conjunction with the accompanying drawings.

### BRIEF DESCRIPTION OF THE DRAWINGS

FIGS. 1A and 1B are views showing the overview of the configuration of a vacuum processing apparatus according to an embodiment of the present invention;

FIGS. 2A and 2B are longitudinal cross-sectional views showing the overview of the configuration of transfer chambers according to the embodiment shown in FIGS. 1A and 1B;

FIGS. 3A and 3B are longitudinal cross-sectional views showing the overview of a buffer chamber of a vacuum processing apparatus according to a modification of the embodiment shown in FIGS. 1A and 1B;

FIG. 4 is a longitudinal cross-sectional view schematically showing a state where maintenance of a vacuum transfer chamber is being carried out according to the modification shown in FIGS. 3A and 3B; and

FIGS. 5A and 5B are longitudinal cross-sectional views showing the overview of the configuration of a buffer chamber of a vacuum processing apparatus according to another modification of the embodiment shown in FIGS. 1A and 1B.

### DESCRIPTION OF THE EMBODIMENTS

An embodiment of the present invention will be described below with reference to the drawings.

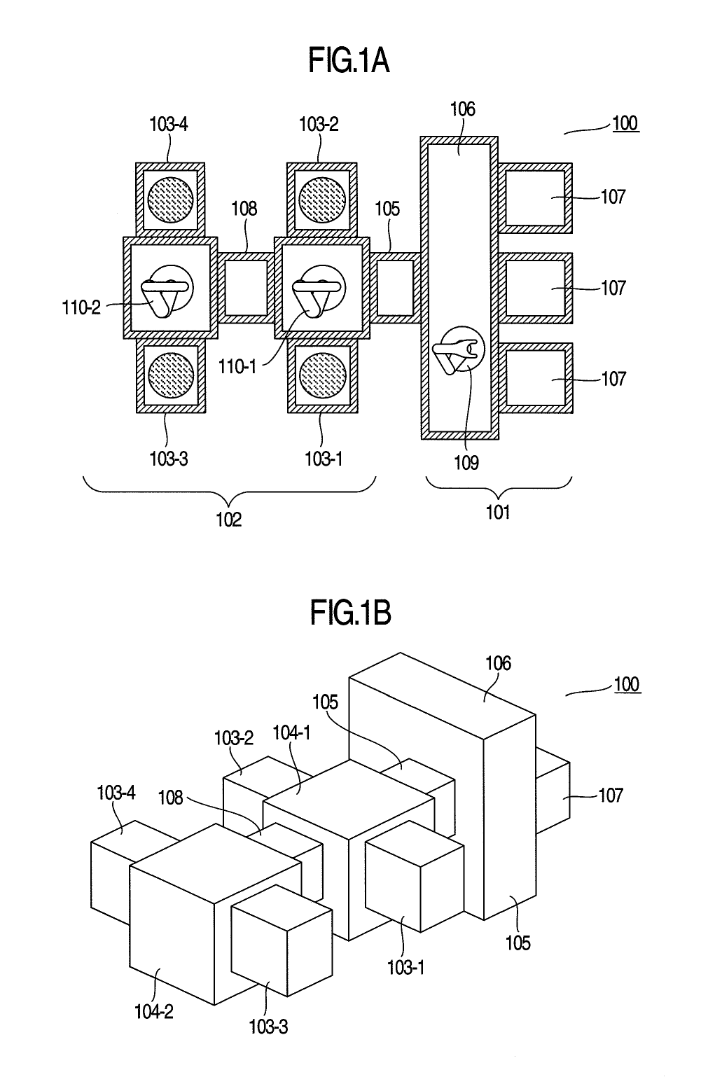

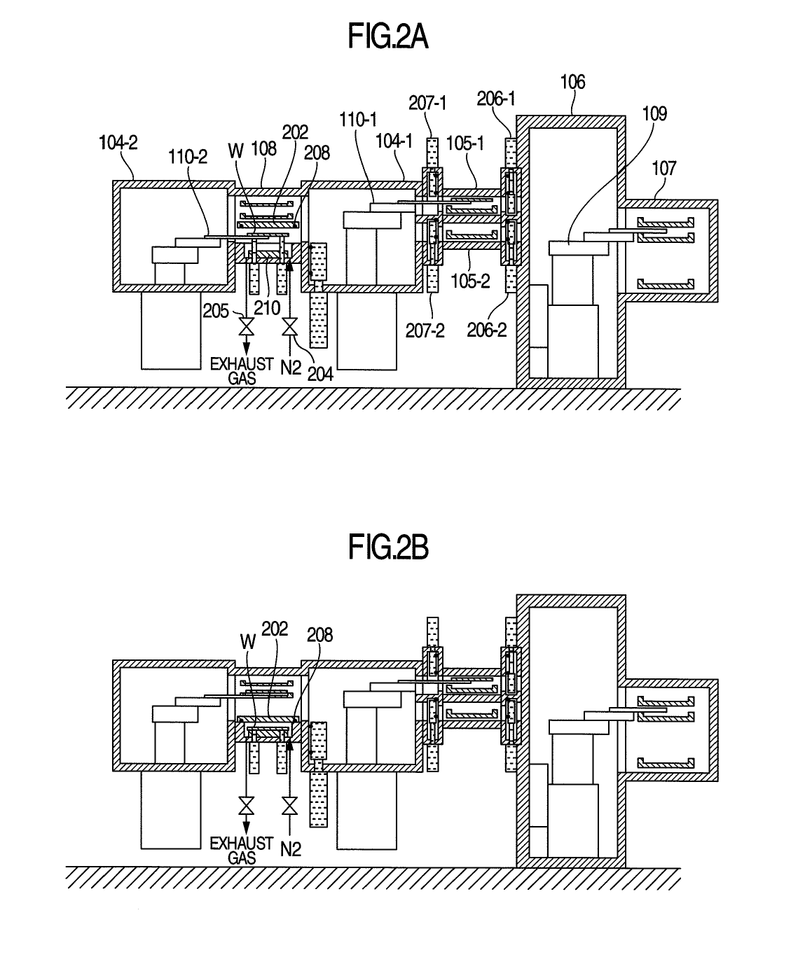

An embodiment of the present invention will be described below with reference to FIGS. 1A, 1B and 2. FIGS. 1A and 1B are views showing the overview of the configuration of a vacuum processing apparatus according to the embodiment of the present invention. FIG. 1A is a top cross-sectional view showing the overall configuration of the vacuum processing apparatus, and FIG. 1B shows a perspective view.

The vacuum processing apparatus according to the present embodiment is divided into front and rear broad blocks and includes an atmospheric block 101 on the front side and a vacuum block 102 which is arranged behind and coupled to the atmospheric block 101. The atmospheric block 101 as one block is a section which transfers a substrate-like sample W, such as a semiconductor wafer, serving as an object to be processed in an interior under atmospheric pressure and performs the operation of, e.g., aligning a specific outer edge end around a center of the sample W. The vacuum block 102 as the other block is a section which transfers a sample W and performs processing and the like under reduced pressure and raises and lowers the pressure while the sample W is mounted.

The atmospheric block 101 includes a housing having in an interior an atmospheric transfer chamber 106 which is set at atmospheric pressure or a pressure slightly higher than atmospheric pressure and a plurality of cassette stages 107 which are attached to a front surface of the housing in the shape of a rectangular parallelepiped and each have a cassette housing a sample W to be processed or cleaned placed on an upper surface. The atmospheric transfer chamber 106 has an atmospheric transfer robot 109 arranged therein, which transfers a sample placed on a distal end portion of an extensible arm between an interior of a cassette mounted on the cassette stage 107 and a lock chamber 105 (to be described later) or a sample alignment machine (not shown) arranged at a left or right end in a horizontal direction of the atmospheric transfer chamber 106 or between the lock chamber 105 and the alignment machine.

The vacuum block 102 includes processing units 103-1, 103-2, 103-3, and 103-4 which each process a sample W transferred into a processing chamber that is an internal space under reduced pressure, vacuum transfer chambers 104-1 and 104-2 which are coupled to the processing units and each include a vacuum transfer robot 110 that transfers a sample W in an interior under reduced pressure, an intermediate chamber 108 which is arranged between the vacuum transfer chambers 104-1 and 104-2 and an interior of which is coupled to the interiors of the vacuum transfer chambers 104-1 and 104-2, and the lock chamber 105 that is arranged between and couples a wall surface on the front surface side of the vacuum transfer chamber 104-1 and the housing of the atmospheric block 101. The vacuum block 102 is a unit which can be reduced in pressure and be maintained at a pressure having a high degree of vacuum.

In each of the processing units 103-1 to 103-4, the cylindrical processing chamber where a sample W is processed is provided in an interior of a vacuum vessel, and a part arranged in an interior of the processing unit is controlled to a temperature meeting a condition for processing of a sample W. In the present embodiment, the temperature is adjusted such that the temperature of a sample W rises to 200° C. to 300° C. during processing. In contrast, the vacuum transfer chambers 104-1 and 104-2, the atmospheric transfer chamber 106, and parts in their interiors and the cassette stages 107 and samples W before processing housed in cassettes are kept at room temperature (the temperature in an interior of a building, such as a clean room, where the vacuum processing apparatus is installed).

A method for transferring a sample W and a method for heating or cooling a sample W which are associated with the vacuum processing apparatus according to the present embodiment will be described with reference to FIGS. 2A and 2B. FIGS. 2A and 2B are longitudinal cross-sectional views showing the overview of the configuration of the transfer chambers according to the embodiment shown in FIGS. 1A and 1B.

In FIGS. 2A and 2B, a cassette housing a sample W in an interior is placed on the cassette stage 107 and is connected to the housing, and the interior of the atmospheric transfer chamber 106 and the interior of the cassette are coupled. After the sample W is carried out into the atmospheric transfer chamber 106 by the atmospheric transfer robot 109, the alignment is performed, as needed. After that, the sample W is transferred into the lock chamber 105.

In the present embodiment, the lock chamber 105 has vertically stacked lock chambers 105-1 and 105-2 and has a stacked configuration as seen from above. In the present embodiment, four gate valves 206-1, 206-2, 207-1, and 207-2 are provided which are arranged at ends, in a longitudinal direction (a lateral direction in FIGS. 2A and 2B) of the apparatus, of the lock chambers 105-1 and 105-2 and each move upward or downward to hermetically close or open an opening at the corresponding end between an interior of the lock chamber 105-1 or 105-2 and the atmospheric transfer chamber 106 or the vacuum transfer chamber 104-1. Note that, in order to inhibit the accuracy of the position of a sample W after transfer from decreasing due to dropping of the sample W during the transfer of the sample W or slippage of the sample W on an upper surface of a hand which is a sample W holding section at the distal end of the arm, the atmospheric transfer robot 109 has means for placing a sample W on the hand such that a minute clearance is formed between a back surface of the sample W and the upper surface of the hand and holding the sample W sucked to stick to the upper surface of the hand by sucking and exhausting gas in an interior of the clearance to reduce pressure.

In the vacuum processing apparatus as described above, a sample W is taken out from a cassette. After the sample W is aligned, the sample W is transferred to either one of the lock chambers 105-1 and 105-2. The wafer is housed in a storage space in the interior of the lock chamber 105-1 or 105-2. After either one of the gate valves 206-1 and 206-2 on the atmospheric transfer chamber 106 side is closed to hermetically seal the lock chamber 105-1 or 105-2 against communication of the interior with the outside, the interior of the lock chamber 105-1 or 105-2 is evacuated through driving of an exhaust pump (not shown), and the pressure of the lock chamber 105-1 or 105-2 is reduced to a pressure having a prescribed degree of vacuum which is equal to that of the vacuum transfer chamber 104-1 or is so close as to be regarded as equal to the pressure. When the pressure in the interior of the lock chamber 105-1 or 105-2 is detected to be not more than the prescribed pressure, either one of the gate valves 207-1 and 207-2 which are arranged on the vacuum transfer chamber side of the lock chamber 105 is opened. The vacuum transfer robot 110 extends an arm to receive the sample W in the interior of the lock chamber 105-1 or 105-2 and contracts the arm to carry out the sample W into the vacuum transfer chamber 104-1.

Since the vacuum transfer robot 110 is arranged in the interior of the vacuum transfer chamber 104-1 that is maintained at the prescribed high degree of vacuum, even if a clearance is formed between a hand for holding a sample W at a distal end portion of the arm of the vacuum transfer robot and a sample W, the sample W cannot be sucked to stick to the hand by a vertical differential pressure resulting from reduction in the pressure in the clearance, as in the atmospheric transfer robot. Thus, for example, a rubber pad or the like which has a high coefficient of friction is attached to an upper surface of the hand of the vacuum transfer robot, and a sample W is mounted on the rubber pad. In the present embodiment, a control unit (not shown) of the vacuum processing apparatus which has a semiconductor device for computation and storage means, such as a semiconductor memory, controls the acting acceleration of the vacuum transfer robot such that frictional force of the rubber pad prevents a sample W from slipping on the hand of the vacuum transfer robot.

The vacuum transfer robot 110 having received the sample W transfers the sample W to any one of the processing units 103-1 to 103-4. The transferred sample W is arranged in the vacuum processing chamber in the interior of the unit and is subjected to predetermined processing using plasma formed in the interior of the processing chamber. In the present embodiment, the two vacuum transfer chambers 104-1 and 104-2 are provided and are connected by the intermediate chamber 108. The intermediate chamber 108 is spatially connected to the vacuum transfer chambers 104-1 and 104-2, and the pressure in the interior is maintained to have a high degree of vacuum equal to those of the vacuum transfer chambers 104-1 and 104-2.

A stage which holds a sample W or a sample W holding pin is present in the interior of the intermediate chamber and is used to pass a sample W between vacuum transfer robots 110-1 and 110-2 (the vacuum transfer robots 110). In the present embodiment, the apparatus is configured to include two vacuum transfer chambers and two processing units for each vacuum transfer chamber (i.e., four vacuum processing chambers in total). However, the apparatus may be configured to include only one vacuum transfer chamber and not to include an intermediate chamber. Alternatively, the apparatus may be configured to include a larger number of vacuum processing chambers by adding third and fourth vacuum transfer chambers.

A sample W before processing is generally at room temperature. The temperature of a sample stage in each vacuum processing chamber is controlled to 200° C. to 300° C. When the sample W at room temperature is mounted on the sample stage at a high temperature, the sample W is heated by heat input from the sample stage. If the sample W is sucked to stick to the sample stage by electrostatic suction force described above, thermal expansion of the sample W may abrade the back surface side of the sample W to produce minute contaminating matters, as described earlier, which results in the problem of, e.g., a product defect.

After the vacuum transfer robot 110 receives the sample W from the lock chamber 105, as described earlier, the vacuum transfer robot 110 transfers the sample W to a buffer chamber 201 instead of transferring the sample W directly into the vacuum processing chamber of one of the processing units 103-1 to 103-4. In the present embodiment, the buffer chamber 201 is a chamber in an interior of a vacuum vessel which is arranged below the intermediate chamber 108 and is a space which can house a sample W, as shown in FIGS. 2A and 2B.

An upper surface of the buffer chamber 201 has an opening which can be opened, and a lid 202 which can move in a vertical direction to open or close the opening is provided in the intermediate chamber 108. The lid 202 is configured to be operable upward and downward by, e.g., an air cylinder (not shown). In the buffer chamber, a soaking plate 210 which is a cylindrical or disc-like member is arranged. The soaking plate 210 serves as a mounting table, an upper surface of which is in contact with a housed sample W or on which the sample W is placed and held with a minute clearance between the sample W and the soaking plate 210.

FIG. 2A shows a state where the vacuum transfer robot 110 carries a sample W into the buffer chamber 201. A state where the lid 202 and lift pins 203 are located at a position as an upper limit in a height direction is shown.

In this state, the vacuum transfer robot 110 transfers the sample W and places the sample W on the lift pins 203. The lift pins 203 loaded with and holding the sample W descend and place the sample W on an upper surface of the soaking plate 210 or stops at a position where a clearance between the sample W and the soaking plate 210 is extremely minute.

FIG. 2B shows a state where the sample W is completely housed in an interior of the buffer chamber 201. In FIG. 2B, a state where the lid 202 descends to close the opening while the sample W is housed is shown. In the state with the closed opening, the buffer chamber 201 and the lid 202 are hermetically sealed with a seal member 208 which is arranged around the opening and between the lid 202 and an upper member of the buffer chamber 201.

The soaking plate 210 is controlled to a high temperature of 200° C. to 300° C. by a heater (not shown). The sample W at room temperature that is arranged on the soaking plate or is separately held at the position with the extremely minute clearance with the soaking plate is heated by heat input from the soaking plate. At this time, if the pressure in the interior of the buffer chamber 201 is low, the efficiency of heat transfer is low, and the sample W cannot be effectively heated.

For this reason, in the present embodiment, a valve 204 is opened to introduce nitrogen gas into the interior of the buffer chamber 201. The pressure in the interior of the buffer chamber 201 is increased to 100 Pa to atmospheric pressure or a pressure so close as to be regarded as equal to the pressure. The increase makes the nitrogen gas serve as a heat transfer factor and allows efficient heating of the sample W.

Note that the heat conduction gas is not limited to nitrogen gas and that an inert gas, such as helium gas, can be used. In the present embodiment, when the control unit detects that the temperature of the sample W is sufficiently increased or detects that a time period over which the sample W is supposed to be sufficiently heated has elapsed, a valve 205 is opened, and the interior of the buffer chamber 201 is evacuated. After the pressure is reduced to be almost equal to those of the interiors of the vacuum transfer chambers 104-1 and 104-2, the lid 202 and the lift pins 203 are lifted, thereby moving the sample W to a position where the sample W can be passed to the vacuum transfer robot 110 above the upper surface of the soaking plate 210.

The sample W sufficiently heated in the interior of the buffer chamber 201 is transferred to any one of the processing units 103-1 to 103-4 coupled to the vacuum transfer chambers 104-1 and 104-2 by either one of the vacuum transfer robots 110-1 and 110-2. The temperature of the sample W at this time is a temperature equal to or so close as to be regarded as equal to the temperature of the sample stage in the vacuum processing chamber of each unit. Even if the sample W is placed on a dielectric film on an upper surface of the sample stage and is electrostatically sucked to stick, as described earlier, the amount of expansion of the sample W due to heat is sufficiently small, which reduces abrasion of a back surface of the sample W and inhibits production of contaminating matters.

If the sample W is not electrostatically sucked to stick to the upper surface of the sample stage in the interior of each processing unit, the temperature of the sample W is sufficiently high from the start of processing in the vacuum processing chamber of the unit. This improves the accuracy of finishing as a processing result or reduces processing time to improve processing efficiency. Although the present embodiment discloses an example where the buffer chamber 201 is arranged below the intermediate chamber 108, the buffer chamber 201 may be arranged above the intermediate chamber 108.

A vacuum processing apparatus with a reduced installation area and high productivity can be realized by providing the vacuum processing apparatus with a configuration in which the buffer chamber 201 arranged below the intermediate chamber 108 and capable of adjusting the temperature of a sample W housed therein and the lid 202 capable of hermetically closing an opening at an upper portion of the buffer chamber 201 are provided, and the lid 202 is operated to open or close, as in the vacuum processing apparatus according to the present embodiment.

The embodiment has illustrated a case where the temperature of the sample stage in each vacuum processing chamber is 200° C. to 300° C. A modification will be illustrated below where the temperature of a sample stage of a vacuum processing chamber is a lower temperature of, for example, −40° C. to 0° C.

As illustrated in the embodiment, a sample W before processing housed in a cassette is generally at room temperature. If the temperature of a sample stage of each processing unit is low, as described above, when a sample W is placed on the sample stage and is sucked to stick by electrostatic suction force, a back surface of the sample W may be abraded due to thermal contraction of the sample W.

In a vacuum processing apparatus including the processing units 103-1 to 103-4, as shown in FIGS. 1A and 1B, for example, a process of transferring a sample W to the processing unit 103-2 via the vacuum transfer chamber 104-1 without taking out the sample W to the atmospheric side and subjecting the sample W to processing, after subjecting the sample W to processing in the processing unit 103-1, is conceivable. A case will be considered here where the temperature of a sample stage of the processing unit 103-1 is, for example, 200° C. and the temperature of a sample stage of the processing unit 103-2 is 0° C.

In this case, if the sample W at a high temperature immediately after the processing in the processing unit 103-1 is transferred to the processing unit 103-2, is placed on an upper surface of the sample stage at a low temperature in an interior of the processing unit 103-2, and is sucked with vacuum to stick, thermal contraction of the sample W may cause damage to the sample W or abrasion between a back surface of the sample W and the upper surface of the sample stage may produce contaminating matters to reduce the yield of the processing.

In order to solve such a problem, in the present modification, a sample W is transferred to the buffer chamber 201 before the sample W is transferred to a processing chamber to carry out processing of the sample W, as in the embodiment, and the temperature of the sample W is cooled to a temperature equal to the temperature of the upper surface of the sample stage in the processing chamber (or a temperature so close as to be regarded as equal) or room temperature (or a temperature so close as to be regarded as equal to room temperature). At this time, the soaking plate 210 of the buffer chamber 201 is adjusted to a prescribed temperature by cooling means (not shown). As the cooling means, making a coolant set at the prescribed temperature flow through a flow path arranged in an interior of the soaking plate 210 or cooling the soaking plate 210 through dissipation of heat by a fin thermally connected to the soaking plate 210 is conceivable.

During the cooling of the sample W, the pressure is adjusted to 100 Pa to a pressure close to atmospheric pressure by introducing nitrogen gas into the interior of the buffer chamber 201, as in the embodiment. If the temperature of the sample W is relatively high, the temperature of the gas in the interior of the buffer chamber 201 rises to lower the efficiency of cooling. For this reason, an inert gas, such as nitrogen, may be made to flow by constantly supplying nitrogen gas into the interior of the buffer chamber 201 through the opened valve 204 and, in parallel, evacuating the buffer chamber 201 through the opened valve 205 or gas in the interior of the buffer chamber 201 may be replaced by periodically alternating introduction of the inert gas into the interior of the buffer chamber 201 and evacuation of the buffer chamber 201.

Assume that a sample W processed at a relatively high temperature in a vacuum processing chamber is transferred to a cassette while the sample W remains at a high temperature, as described earlier, in the modification. When a hand arranged at a distal end portion of an arm of the atmospheric transfer robot 109 is sucked with vacuum to stick to the sample W, only a contact surface between the sample W and the hand may be rapidly cooled, and thermal stress may cause damage to the sample W. Alternatively, if the temperature of the sample W is not less than the heatresistant temperature of the cassette, the cassette may be damaged. Even in this case, as in the modification, after the sample W at a high temperature after processing is transferred to the buffer chamber 201, and the temperature of the sample W is lowered to a prescribed temperature or a lower temperature which does not cause damage, the sample W is transferred to the cassette. This inhibits occurrence of the above-described problems.

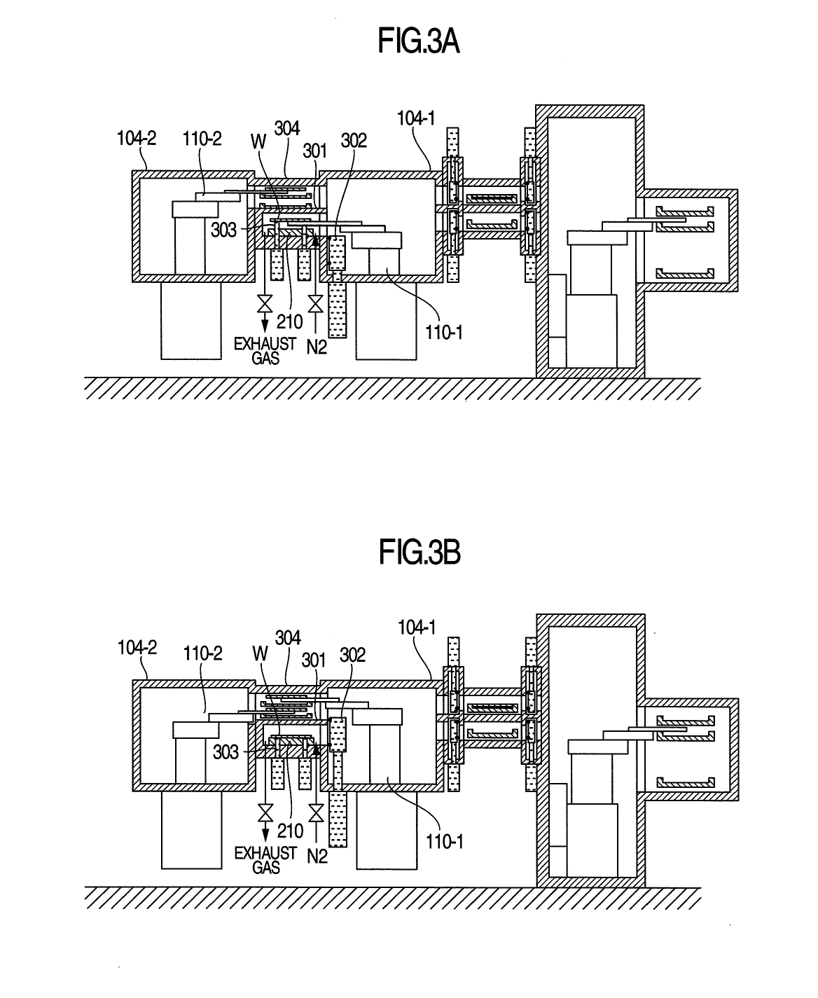

Another modification of the vacuum processing apparatus according to the embodiment of the present invention that has a buffer chamber 301 with a different configuration will be shown in FIGS. 3A and 3B. FIGS. 3A and 3B are longitudinal cross-sectional views showing the overview of the configuration of a vacuum processing apparatus according to a modification of the embodiment shown in FIGS. 1A and 1B.

In the modification shown in FIGS. 3A and 3B, the buffer chamber 301 has an opening at a side surface, particularly on the vacuum transfer chamber 104-1 side. As in the example shown in the embodiment or the modification, a sample W is carried into an interior of the buffer chamber 301 and is mounted on the soaking plate 210 or is moved to and held at a height position with a minute clearance with the soaking plate 210. The sample W before processing or after processing is heated or cooled. The features of the present modification are that the buffer chamber 301 is arranged immediately below an intermediate chamber 304 and that the opening at the side surface of the buffer chamber 301 and an opening at a side surface of the intermediate chamber 304 have the same shape or the same size. The opening of the buffer chamber 301 is opened or closed by a gate valve 302. As described earlier, the buffer chamber 301 is configured such that the pressure in the interior of the buffer chamber 301 can be increased or reduced and such that the opening at the side surface of the intermediate chamber 304 can be opened or hermetically closed by the gate valve 302.

FIG. 3A shows a state where the gate valve 302 is opened, and the vacuum transfer robot 110-1 carries a sample W into the interior of the buffer chamber 301. FIG. 3B shows a state where the gate valve 302 closes the opening of the buffer chamber 301, and the sample W is heated or cooled in the interior of the buffer chamber 301.

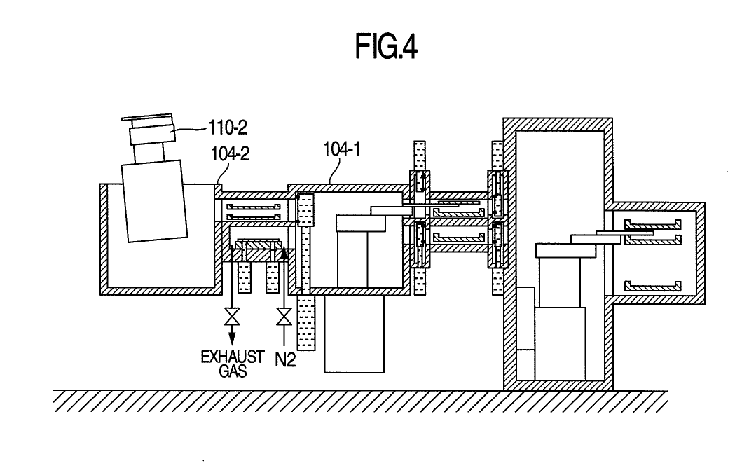

In the present modification, the vacuum transfer robots 110-1 and 110-2 each can make a hand at a distal end portion of an arm enter (can access) an interior of the intermediate chamber 304 while the interior of the buffer chamber 301 is hermetically sealed with the gate valve 302. FIG. 4 shows a state where an interior of the vacuum transfer chamber 104-2 coupled to the side not closed is opened to the atmosphere and is maintained or checked while the gate valve 302 hermetically closes the opening at the one side surface of the intermediate chamber 304.

FIG. 4 is a longitudinal cross-sectional view schematically showing a state where maintenance of the vacuum transfer chamber is being carried out in the modification shown in FIGS. 3A and 3B. In the present modification, a lid at an upper portion of a vacuum vessel constituting the vacuum transfer chamber 104-2 is opened, the interior of the vacuum transfer chamber 104-2 is exposed to an air atmosphere, and maintenance, such as replacement of a main body or a part of the vacuum transfer robot 110-2, is being carried out. As described earlier, since the opening of the intermediate chamber 304 is hermetically closed by the gate valve 302, an interior of the vacuum transfer chamber 104-1 is maintained at a prescribed degree of vacuum equal to or slightly higher than that of an interior of a vacuum processing chamber in an interior of a processing unit coupled to the vacuum transfer chamber 104-1. In parallel with making the interior of the vacuum transfer chamber 104-2 open to an atmospheric-pressure atmosphere and performing maintenance work, such as cleaning the interior of the vacuum transfer chamber 104-2 or replacing a part of the vacuum transfer robot 110-2, processing on a sample W transferred from a cassette can be continued in the vacuum transfer chamber 104-1 and other processing units coupled to the vacuum transfer chamber 104-1.

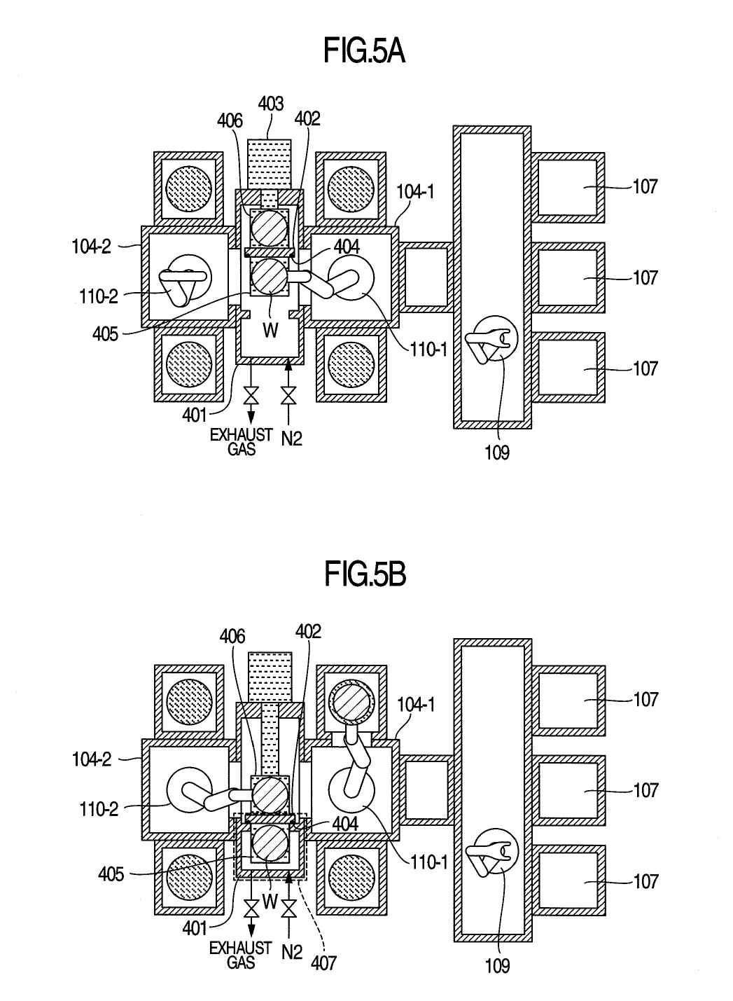

Another modification of the vacuum processing apparatus that has different versions of the intermediate chamber 108 and the buffer chamber 201 will be illustrated with reference to FIGS. 5A and 5B. FIGS. 5A and 5B are longitudinal cross-sectional views showing the overview of the configuration of a buffer chamber of a vacuum processing apparatus according to another modification of the embodiment shown in FIGS. 1A and 1B.

In the present modification, a buffer chamber 401 which is coupled to the vacuum transfer chambers 104-1 and 104-2 is arranged between the vacuum transfer chambers 104-1 and 104-2. In an interior of the buffer chamber 401, a soaking stage 405 and a transfer intermediate stage 406 are arranged, and a vacuum flange 402 which separates the soaking stage 405 and the transfer intermediate stage 406 is provided between the soaking stage 405 and the transfer intermediate stage 406. In the present modification, the soaking stage 405, the transfer intermediate stage 406, and the vacuum flange 402 are integrally constructed as one member, and the sections are structured to be operable in a horizontal direction by a driving device 403, such as an air cylinder, which is coupled to a side wall on the upper side in FIGS. 5A and 5B (in a lateral direction in the actual machine) of the buffer chamber.

FIG. 5A shows a state where the vacuum transfer robot 110-1 mounts a sample W on the soaking stage 405. At this time, the interior of the buffer chamber 401 is spatially connected to the vacuum transfer chambers 104-1 and 104-2 and is maintained at a degree of vacuum equal to or slightly higher than that of a vacuum processing chamber. The soaking stage 405, the transfer intermediate stage 406, and the vacuum flange 402 that are coupled to a distal end portion of a shaft of an actuator extending in the horizontal direction are moved in a direction of the shaft (a vertical direction in FIGS. 5A and 5B) in the interior of the buffer chamber 401 by the driving device 403 that is arranged outside either one of side surfaces (the side surface on the upper side in FIGS. 5A and 5B) in the horizontal direction of the buffer chamber 401 (FIG. 5B).

In the state shown in FIG. 5B, a flange section which protrudes from a wall surface toward the central side in the interior of the buffer chamber 401 and an outer surface of the vacuum flange 402 coupled to the actuator are made to face each other, the flange section and the vacuum flange 402 with a seal member 404 sandwiched therebetween partition a space in the buffer chamber 401, and one space 407 where the moved soaking stage 405 is housed is hermetically closed against the other space. As in the embodiment and modifications, a sample W before processing or after processing is heated or cooled. During the heating or cooling, the vacuum transfer robots 110-1 and 110-2 can access the transfer intermediate stage 406, and the sample W can be passed between the vacuum transfer chambers 104-1 and 104-2.

By arranging the transfer intermediate stage and the soaking stage for heating or cooling a sample W side by side in a horizontal direction and moving the vacuum transfer robots in the horizontal direction, as in the present modification, the vertical height of a vacuum processing apparatus can be reduced to a necessary and sufficient value. This leads to reduction in the size of a vacuum processing apparatus and reduction in manufacturing costs.

It should be further understood by those skilled in the art that although the foregoing description has been made on embodiments of the invention, the invention is not limited thereto and various changes and modifications may be made without departing from the spirit of the invention and the scope of the appended claims.

1. A vacuum processing apparatus comprising a plurality of processing units, each of which has a processing chamber arranged in an interior of a vacuum vessel and reduced in pressure and subjects a sample to processing inside the processing chamber, a plurality of vacuum transfer chambers which are coupled to the processing units and each have an interior where the sample is transferred under reduced pressure, and an intermediate chamber which is arranged between and coupled to two of the vacuum transfer chambers and has, in an interior, a space where the transferred sample is housed, wherein
the apparatus further comprises a buffer chamber which is coupled to the intermediate chamber and is capable of housing the sample arranged in the interior of the vessel, a mounting stage which is arranged in the buffer chamber and is adjusted to a prescribed temperature and on which the sample is placed, an opening which is arranged between the buffer chamber and the interior of the intermediate chamber and through which the sample is taken in or out, and a lid member which opens or hermetically closes the opening, and
the sample is transferred between the processing unit and a lock chamber via the buffer chamber.

2. The vacuum processing apparatus according to claim 1, wherein the sample before or after processing in the processing unit is transferred to the buffer chamber, and temperature adjustment is performed such that temperature of the sample reaches the prescribed temperature.

3. The vacuum processing apparatus according to claim 1, wherein, in a state where the lid member closes the opening, a transfer robot which is arranged in each of the plurality of vacuum transfer chambers is capable of making an arm distal end portion of the transfer robot enter the interior of the intermediate chamber and transferring the sample between the interior of the intermediate chamber and the interior of the vacuum transfer chamber.

4. The vacuum processing apparatus according to claim 1, wherein the buffer chamber is arranged below the intermediate chamber, the opening is arranged at an upper portion of the buffer chamber, and the lid moves in a vertical direction to open or hermetically close the buffer chamber.

5. The vacuum processing apparatus according to claim 1, further comprising a gate valve which is capable of opening or hermetically closing the buffer chamber arranged above or below the intermediate chamber and the intermediate chamber, wherein the gate valve selectively closes either one of an opening of the intermediate chamber and an opening of the buffer chamber.
